(19) United States
(12) Patent Application Publication
(10) Pub. No.: US 2012/0178219 A1
(43) Pub. Date: Jul. 12, 2012

(54) METHODS FOR VACUUM ASSISTED UNDERFILLING

(75) Inventors: Alec J. Babiarz, Encinitas, CA (US); Thomas L. Ratledge, San Marcos, CA (US); Horatio Quinones, San Marcos, CA (US)

(73) Assignee: NORDSON CORPORATION, Westlake, OH (US)

(21) Appl. No.: 13/004,198

(22) Filed: Jan. 11, 2011

(51) Int. Cl. H01L 21/56

(52) U.S. Cl. 438/127; 257/E21.503

(57) ABSTRACT

Methods for applying an underfill with vacuum assistance. The method may include dispensing the underfill onto a substrate proximate to at least one exterior edge of an electronic device attached to the substrate. A space between the electronic device and the substrate is evacuated through at least one gap in the underfill. The method further includes heating the underfill to cause the underfill to flow into the space. Because a vacuum condition is supplied in the open portion of the space before flow is initiated, the incidence of underfill voiding is lowered.

### BACKGROUND

The invention relates generally to methods for applying an underfill between an electronic device and a substrate.

It is typical for an electronic device, such as a flip chip, chip scale package (CSP), ball grid array (BGA) or package on package assembly (PoP) to include a pattern of solder bumps that, during mounting, are registered with pads on a substrate, or joined using another type of interconnect technology such as copper pillars or other types of thermal compression bonding interconnects. The substrate can be a printed circuit board, electronic chip or wafer, for example. The solder is reflowed by heating and, following solidification, solder joints connect the electronic device and the substrate. Underfill may be used to fill the open space between the electronic device and the substrate that remains between the reflowed solder balls. The underfill protects the solder joints against various adverse environmental factors, redistributes mechanical stresses due to shock, and prevents the solder joints from moving under strain during thermal cycles.

Pockets of gas or air may be trapped in the underfill during conventional underfilling that leads to the formation of voids in the underfill. Because the voids are unfilled by underfill, unsupported solder joints adjacent to voids may not be adequately protected against cold flow when exposed to strain from thermal expansion during operation or to mechanical shock caused by dropping the assembled end product, such as a cell phone, that includes the underfilled electronic device. Voids at solder joints prevent the solder bump from being in held in a state of hydrostatic compression and strain restraint, which may increase solder joint fatigue and thereby increase the probability of solder joint cracking.

Therefore, improved methods are needed for applying an underfill that reduces the probability of forming voids in the underfill.

### SUMMARY OF THE INVENTION

In one embodiment, a method is provided for distributing an underfill into the space between the reflowed solder balls which connect an electronic device to a substrate. The method includes providing the underfill onto the substrate near to at least one exterior edge of the electronic device with at least one gap in the underfill, providing an air path to the space between the electronic device and substrate and then evacuating that space through the gap, or gaps, to provide a vacuum condition in the space. After evacuating the space, the underfill is heated above room temperature to cause capillary flow of the underfill from the exterior edge, or edges, into the space between the electronic device and substrate and around the reflowed solder balls. The underfill can be provided as a material which is solid at room temperature and is positioned by pick and place equipment onto the substrate, and thereafter becomes liquid at elevated temperatures, or as a liquid material that can be dispensed onto the substrate by, for example, a valve or dispenser.

Another embodiment of the invention is directed to a method of providing an underfill on a substrate upon which electronic device is mounted by electrically conductive joints and is separated from the substrate by a space. The space has an open portion that is unoccupied by the conductive joints. The method includes providing the underfill onto the substrate proximate to at least one exterior edge of the electronic device, and evacuating the space to provide a vacuum condition in the open portion of the space. After evacuating the space to a vacuum condition, the underfill is heated to a temperature above room temperature to cause flow of the underfill from the at least one exterior edge into the open portion of the space.

### BRIEF DESCRIPTION OF THE DRAWING

The accompanying drawings, which are incorporated in and constitute a part of this specification, illustrate exemplary embodiments of the invention and, together with a general description of embodiments of the invention given above, and the detailed description given below, serve to explain the principles of the embodiments of the invention.

FIG. 1 is a side view of an electronic device mounted to a substrate by an array of solder balls and with underfill dispensed along a side edge of the electronic device.

FIG. 1A is a side view similar to FIG. 1 in which the underfill has moved into the open space between the electronic device and substrate that is unoccupied by the solder balls.

FIG. 2 is a flow chart of a procedure for vacuum underfilling in accordance with an embodiment of the invention.

FIGS. 3A-C are diagrammatic top views illustrating a sequence for vacuum underfilling beneath an electronic device mounted on a substrate in accordance with an embodiment of the invention.

FIGS. 4A-C are diagrammatic top views similar to FIGS. 3A-C in accordance with another embodiment of the invention.

FIGS. 5A-C are diagrammatic top views similar to FIGS. 3A-C in accordance with yet another embodiment of the invention.

FIGS. 5D, 5E and 5F are a diagrammatic top views similar to FIG. 5A in which the underfill is dispensed onto the substrate with, respectively, an L pattern, a U pattern, and an I pattern.

FIG. 5G is a diagrammatic top view similar to FIG. 5A in which the underfill is dispensed onto the substrate with no gaps.

FIG. 6 is a schematic representation of a vacuum underfilling system in accordance with an embodiment of the present invention.

### DETAILED DESCRIPTION

Generally, the embodiments of the invention are directed to a vacuum-assisted process for underfilling an electronic device mounted on a substrate by an array of solder balls. Underfill is dispensed or otherwise applied in one or more lines around the edges of an unheated electronic device, which is mounted to an unheated substrate by means of an array of reflowed solder balls. Preferably, at least one gap is left in the one or more lines of underfill. The substrate is transported into a vacuum chamber, before significant capillary underfilling (and air or gas entrapment) occurs, and a vacuum is applied. While the vacuum is being applied, the gap, or gaps, in the one or more lines of underfill allows air to flow out from under the device through the gap(s), to establish a vacuum condition (i.e., a pressure less than atmospheric pressure) under the electronic device between the electronic device and the substrate. An alternative, less preferred process, is to provide no gap in the underfill and to rely upon the air trapped under the device to bubble through the underfill when the device is placed under vacuum. Under either process, while the vacuum condition is being maintained, the electronic device and substrate are heated to cause the underfill to completely flow under the electronic device into the spaces between the reflowed solder balls. Underfilling in the presence of the vacuum condition means any void entrapped in the underfill will be partially evacuated of gases commensurate with the level of the applied vacuum. The vacuum pressure applied must not be lower than the vapor pressure of the underfill, otherwise the underfill will boil and the process will become less stable. The vacuum chamber is then vented. Any voids present in the underfill will now collapse because of the evacuated condition and become filled with underfill. The underfilled electronic device and substrate are then moved out of the vacuum chamber.

The embodiments of the invention also apply to other interconnect technologies, in addition to solder bumps, for creating conductive joints between the electronic device and the substrate, such as copper pillars and other thermal compression bonding interconnect technologies.

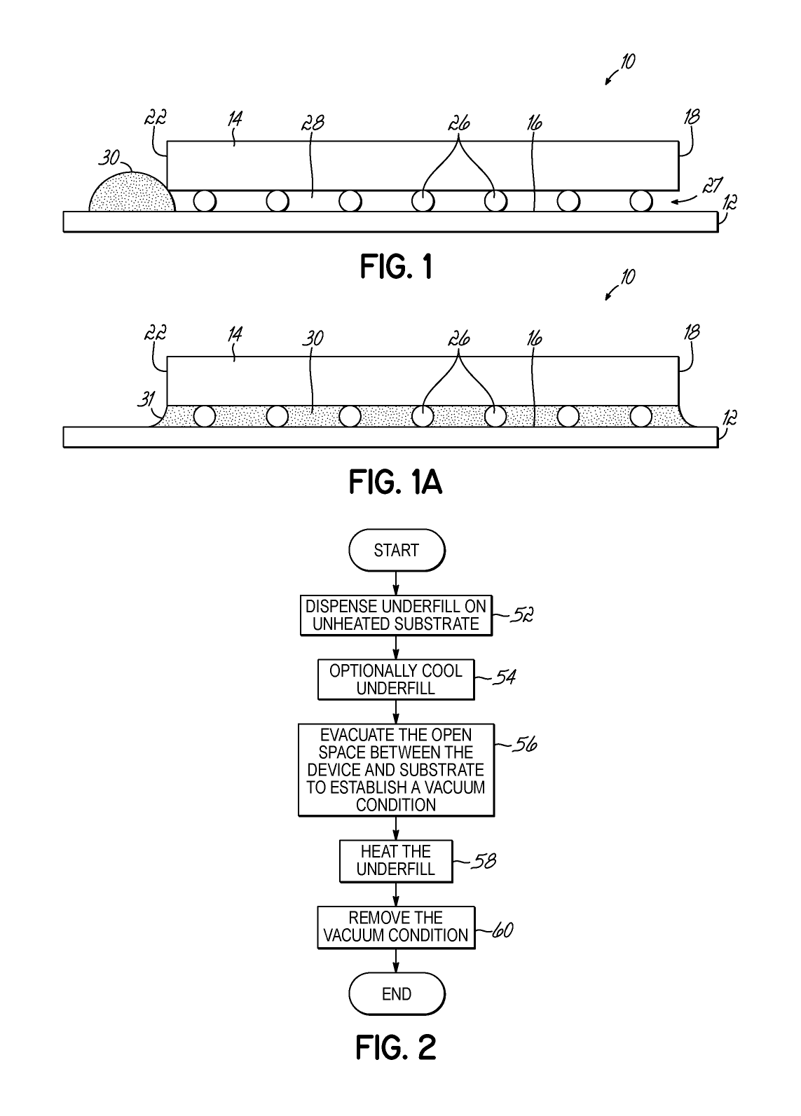

With reference to FIG. 1, an assembly 10 includes a substrate 12, such as a printed circuit board, and an electronic device 14 that is mounted to a surface 16 of the substrate 12. In representative embodiments, the electronic device 14 may be a flip chip, chip scale package (CSP), ball grid array (BGA) or package on package assembly (PoP), for example. Likewise, the substrate 12 may be a printed circuit board (PCB), electronic chip or wafer, for example, or any substrate or interposer used in semiconductor packaging of electronic devices.

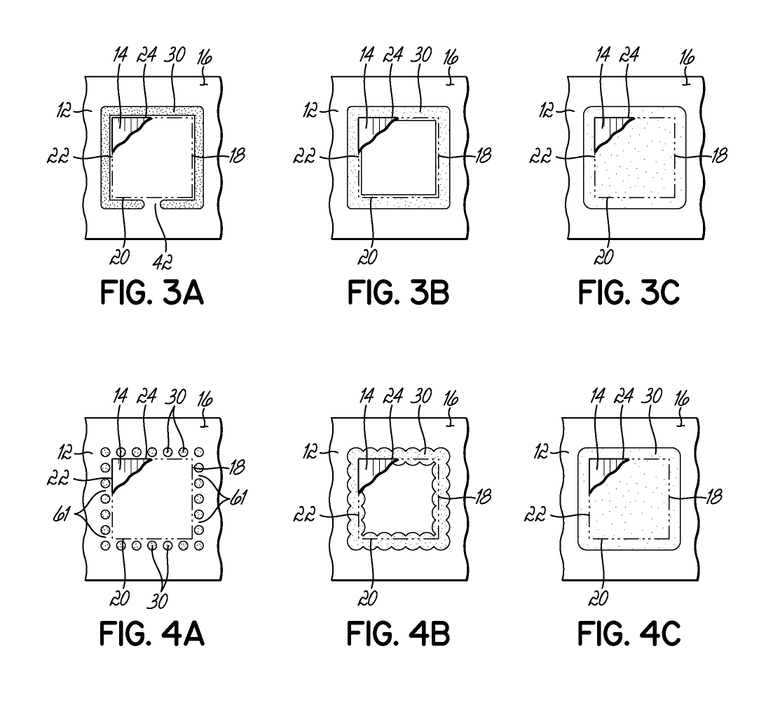

With reference to FIGS. 1, 1A, and 3A, the electronic device 14 has a footprint on the substrate 12 such that the substrate 12 is exposed adjacent to each of the side or exterior edges 18, 20, 22, 24 of the electronic device 14. Solder joints 26 mechanically and electrically connect the electronic device 14 with the substrate 12. A space 28 is defined between the electronic device 14 and substrate 12 and a portion of the space 28 is open (i.e., unoccupied) and unfilled by the solder joints 26 that may have a representative form of solder balls. At each of the exterior edges 18, 20, 22, 24, a gap 27 is defined between the electronic device 14 and the substrate 12. The gap 27 communicates with the space 28.

An underfill 30 is used to fill the space 28 between the electronic device 14 and the substrate 12, as shown in FIG. 1A. In one example, the underfill 30 is a curable non-conductive silicon dioxide particle filled epoxy that is fluid when applied to the substrate 12 and flows by capillary action. Other types of underfill can be used including those that are solid at room temperature or are frozen. Underfills are typically filled with small particles of glass, for example to provide the desired properties in the cured underfill. When cured and hardened, the underfill forms a strongly bonded, cohesive mass.

With reference to FIG. 2, a procedure for vacuum underfilling in accordance with an embodiment of the invention is described. In the FIG. 2 embodiment, a liquid underfill is dispensed onto the substrate. Instead of dispensing, the underfill could be applied in solid form in position to buy a pick and place machine, for example, as mentioned above. In block 52, liquid underfill 30 is dispensed onto the substrate 12. The underfill 30 may be applied as one or more continuous lines (FIG. 3A) proximate to one or more exterior edges 18, 20, 22, 24 of the electronic device 14. Typically, the dispensed amount of underfill 30 is equal to the volume of the open space 28 under the electronic device 14 plus the fillet 31 (FIG. 1B) that forms along the perimeter of the device 14 after the underfill operation has been completed. The substrate 12 is unheated when the underfill 30 is applied and a gap 42 (FIG. 3A) is preferably present in the underfill 30 so that an air path to the open portion of space 28 through the gap 42 is maintained. As discussed above, the less preferred method is not to leave a gap, and to rely on air trapped under the electronic device 14 to bubble through the underfill 30.

The underfill 30 may be applied to the substrate 12 using multiple different types of dispensers and in multiple different ways. For example and although the invention is not so limited, a series of droplets of underfill 30 may be dispensed onto the surface 16 of the substrate 12 from a moving jetting dispenser that is flying above the surface 16.

In block 54, the underfill 30 is cooled when dispensed onto the substrate 12. In one embodiment, the substrate 12 is cooled, for example, by one or more thermoelectric coolers to a temperature below room temperature and the underfill 30 cools shortly after application to approximately the temperature of the substrate 12. Alternatively or in addition to cooling the substrate 12, the underfill 30 may be cooled in the dispenser before being dispensed onto the substrate 12. In one embodiment, the underfill 30 is cooled to a temperature in the range of 0° C. to 10° C. Cooling increases the viscosity of the underfill 30, which further prevents or reduces capillary action flow into the open portion of the space 28 between the electronic device 14 and the substrate 12.

In block 56, the unfilled portion of space 28 is evacuated to a sub-atmospheric pressure through the gap 42 in the underfill 30 to establish a vacuum condition (i.e., a pressure less than atmospheric pressure) in space 28. Or, if no gap has been provided, the gas will bubble through the underfill 30. To create the vacuum, in one embodiment, the substrate 12, which carries the electronic device 14 and underfill 30, are moved into a vacuum chamber, sealed inside the chamber, and the vacuum chamber is evacuated to a sub-atmospheric pressure. In one embodiment, a suitable sub-atmospheric pressure for the vacuum is greater than or equal to 25 inches of Hg (about 95 Torr) to 26 inches of Hg (about 100 Torr). In any event, the sub-atmospheric pressure is limited such that the physical properties of the underfill are not significantly or detrimentally modified.

Any suitable technique may be used for moving the substrate 12 into and out of the vacuum chamber, and conventional vacuum systems are familiar to a person having ordinary skill in the art. The substrate 12 is preferably transferred into the vacuum chamber before the occurrence of significant capillary underfilling (and air or gas entrapment).

In block 58, after the vacuum chamber is evacuated, and while the vacuum condition is being maintained, the underfill 30 is heated to a temperature in excess of room temperature, for example to a temperature in a range of 30° C. to 120° C. The underfill 30 may be heated by heating the substrate 12, electronic device 14 or both and in any desired sequence to direct flow. In response to the heating, the underfill 30 flows by capillary action through the narrow gap 27 from each of the exterior edges 18, 20, 22, 24 into the space 28 and around the reflowed solder balls. Because the open portion of the space 28 is evacuated, the underfill 30 can flow across the space 28 such that any void entrapped in the underfill 30 will be evacuated of gases to the vacuum level.

In block 60, after sufficient time has been provided for complete capillary flow to have occurred, then the vacuum condition is removed and atmospheric pressure is restored. For example, the vacuum chamber may be vented to provide the atmospheric pressure condition. Under the influence of atmospheric pressure, any voids present in the underfill 30 will collapse because of their evacuated state of sub-atmospheric pressure and become filled with underfill 30 (FIG. 3C). The substrate 12 is then transferred from the vacuum chamber to a curing oven and the underfill 30 is cured.

With reference to FIGS. 4A-4C and in alternative embodiments, the underfill 30 may be applied proximate to the exterior edges 18, 20, 22, 24 of the electronic device 14 as a series of disconnected regions (FIG. 4A) with multiple gaps 61. In FIG. 4B, the gaps 61 disappear as the underfill 30 is heated after evacuating the open portion of space 28 to a vacuum condition. In FIG. 4C, the underfill 30 flows beneath the device 14.

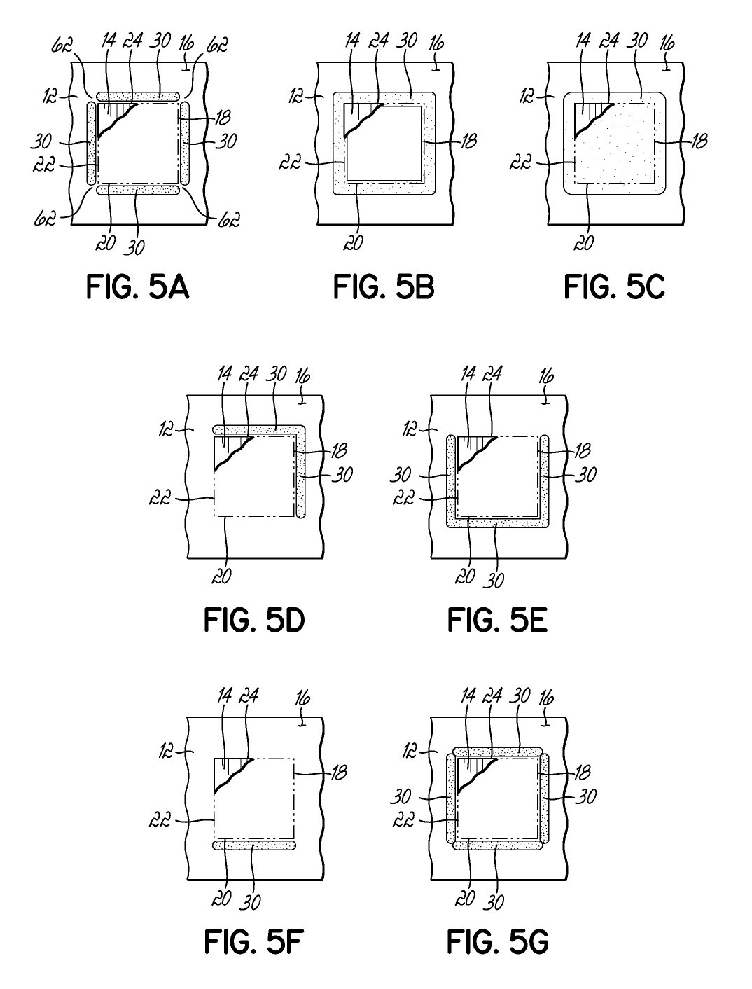

With reference to FIGS. 5A-5E and in alternative embodiments, the underfill 30 may be applied proximate to one or more of the exterior edges 18, 20, 22, 24 of the electronic device 14 in one or more passes. In this case, FIG. 5A shows a line of underfill applied along each of the four edges of the device, with a gap 62 are present at each corner between each pair of exterior edges 18, 20, 22, 24. In FIG. 5B, the underfill 30 is heated after evacuating the space 28 through the gaps 62 to a vacuum condition. In FIG. 5C, the underfill 30, in the heated state, flows beneath the device 14.

In an alternative embodiment and as shown in FIG. 5D, the underfill 30 could be provided as lines using an L pass along exterior edges 18 and 24 of the electronic device 14. In this case, a gap is present along the exterior edges 20 and 22. In another alternative embodiment and as shown in FIG. 5E, the underfill 30 could be provided as lines using a U pass along exterior edges 18, 20, 22 of the electronic device 14 but not along exterior edge 24 of the electronic device 14. In another alternative embodiment and as shown in FIG. 5F, the underfill 30 could be provided as a line using an I pass along exterior edge 20 of the electronic device 14 but not along exterior edges 18, 22, and 24. As probably the least preferred alternative embodiment and as shown in FIG. 5G, the underfill 30 could be applied as lines along all four edges 18, 20, 22 and 24 and in an overlapping manner with no gaps defined at the corners. In this case, the air, or gas, trapped under the electronic device 14 will bubble through the underfill 30 when the vacuum is applied.

The lines of underfill, in addition to being applied in the preferred method from a non-contact jetting valve, such as the DJ 9000 sold by Nordson ASYMTEK of Carlsbad, Calif., could alternatively be applied as solid preforms of epoxy. The solid preforms are placed on the substrate 12 and then melted upon the application of heat. The solid preforms could be placed into position by a pick and place machine or mechanism.

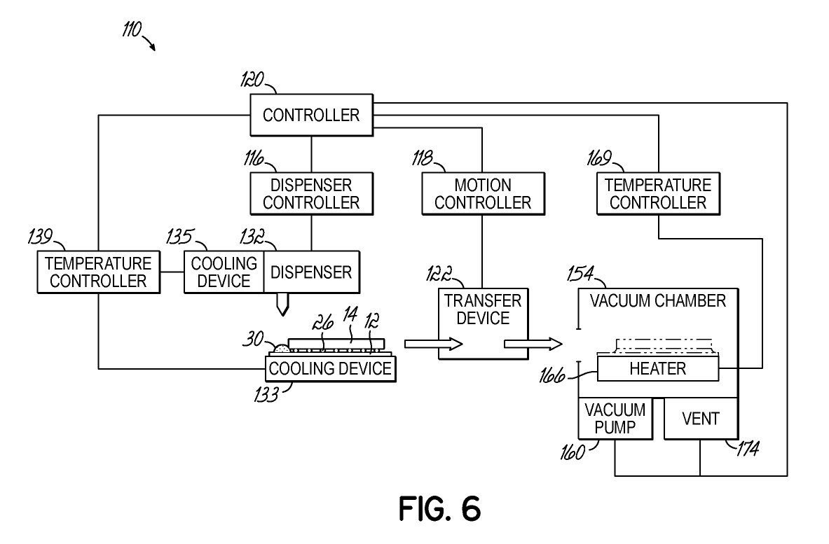

With reference to FIG. 6, a system 110 for use in vacuum underfilling is configured to dispense amounts of the underfill 30 on the substrate 12 upon which the electronic device 14 is mounted by reflowed solder balls, or another interconnect technology, and is separated from the substrate 12 by the space 28. The space 28 has an open portion that is not occupied by the conductive joints 26, which in this case are in the form of reflowed solder balls.

A controller 120, which is electrically coupled with a motion controller 118 and a dispenser controller 116, coordinates the overall control for the system 110. Each of the controllers 116, 118, 120 may include a programmable logic controller (PLC), a digital signal processor (DSP), or another microprocessor-based controller with a central processing unit capable of executing software stored in a memory and carrying out the functions described herein, as will be understood by those of ordinary skill in the art.

The system 110 preferably includes a cooling device 133 and a cooling device 135 that is coupled with the dispenser 132. The cooling device 133 is configured to cool the substrate 12 such that the underfill 30 cools when dispensed onto the substrate 12. The cooling device 135 is configured to cool the underfill 30 such that the underfill 30 is cooled before dispensing onto the substrate 12. The cooling devices 133, 135 are preferred, and optional, and may be respectively operated by a temperature controller 139 under the control of controller 120 to reduce the temperature of the substrate 12 to below room temperature and/or to reduce the temperature of a portion of the dispenser 132 to below room temperature.

The system 110 includes a dispenser 132, which may be a jetting dispenser, used to dispense the amounts of the underfill. Downstream from the dispenser 132, the system 110 further includes a vacuum chamber 154 configured to permit access for inserting and removing each assembly 10 and configured to provide a sealed condition in which an interior space of the vacuum chamber 154 is isolated from the surrounding atmospheric-pressure environment. A vacuum pump 160 is coupled with the interior space of the vacuum chamber and is configured to evacuate the interior space as operated by the controller 120. A vent 174 is used under the control of the controller 120 to admit gas to the interior space to raise the chamber pressure. The controller 120 supplies motion instructions to the motion controller 118 to operate a transfer device 122 used to move the substrate 12, which is carrying the underfill 30, into the vacuum chamber 154.

A heater 166 is disposed inside the vacuum chamber 154 and is configured to be powered by a temperature controller 169 linked with the controller 120. Heat is transferred from the heater 166 to each substrate 12. In one embodiment, the temperature of the substrate 12 and underfill on the substrate ranges from 30° C. to 120° C.

In use, the substrate 10 is moved to a location beneath the dispenser 132 and underfill is dispensed or otherwise applied. In the representative embodiment, the controller 120 sends commands to the motion controller 118 to cause the transfer device 122 to move the dispenser 32 and the controller 120 sends commands to the dispenser controller 116 to cause the dispenser 32 to dispense the underfill in one or more lines around the exterior edges 18, 20, 22, 24 of the electronic device 14. The substrate 12 is not heated during the dispensing operation. Preferably, at least one gap is left in the one or more lines of underfill 32. For a jetting dispenser 132, the dispenser controller 16 triggers the jetting of droplets at appropriate times during the movement such that the droplets will impact at a desired location on the substrate 12. Each dispensed droplet contains a small volume of the underfill, which is typically controlled with high precision by the dispenser controller 16.

In one embodiment, the cooling device 133 may be used to cool the substrate 12 so that the underfill 30 cools to a temperature below room temperature upon contact with the substrate 12. Alternatively, the cooling device 135 coupled with the dispenser 132 may be used to cool the underfill 30 before dispensing.

After the dispensing operation is completed and before significant capillary underfilling (and air or gas entrapment) occurs, the controller 120 sends commands to the motion controller 118 to cause the transfer device 122 to transport the assembly 10 and dispensed underfill 30 on the substrate 12 into the vacuum chamber 54. Once the assembly 10 and dispensed underfill 30 on the substrate 12 are isolated inside the vacuum chamber 54 from the ambient environment, the controller 120 causes the vacuum pump 160 to evacuate the interior space inside the vacuum chamber 154. While the vacuum is being applied, each gap allows a vacuum condition (i.e., a pressure less than atmospheric pressure) to be established under the electronic device 14 between the electronic device 14 and the substrate 12 or, if there is no gap, then the gas bubbles through the underfill to create a vacuum condition under the electronic device 14.

When a suitable vacuum pressure exists inside the vacuum chamber 154 and with the vacuum condition being maintained, the controller 120 causes the temperature controller 169 to operate the heater 166, which heats the substrate 12, electronic device 14, and underfill 30. The elevated temperature encourages the underfill 30 to flow into the open portion of the space beneath the electronic device 14. The underfill 30 completely flows under the electronic device 14 and into the spaces between the reflowed solder balls. Underfilling in the presence of the vacuum condition means any void entrapped in the underfill will be partially evacuated of gases. After flow ends, the controller 120 sends commands to the motion controller 118 to cause the vent 174 to admit gas to the vacuum chamber 154 so that the pressure inside the vacuum chamber 154 is returned to atmospheric pressure. Any voids present in the underfill 30 collapse because of the evacuated condition and become filled with underfill 30. The substrate 12 with the underfilled electronic device 14 is transferred out of the vacuum chamber 154 to, for example, a curing oven (not shown)

While the invention has been illustrated by the description of one or more embodiments thereof, and while the embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and methods and illustrative examples shown and described. Accordingly, departures may be made from such details without departing from the scope or spirit of Applicant's general inventive concept.

What is claimed is:

1. A method of providing an underfill on a substrate upon which electronic device is mounted by electrically conductive joints and is separated from the substrate by a space, the space having an open portion that is unoccupied by the conductive joints, the method comprising:
providing the underfill onto the substrate proximate to at least one exterior edge of the electronic device;
evacuating the space to provide a vacuum condition in the open portion of the space; and
after evacuating the space to a vacuum condition, heating the underfill to a first temperature above room temperature to cause flow of the underfill from the at least one exterior edge into the open portion of the space.

2. The method of claim 1 further comprising:
before evacuating the space, cooling the underfill to a second temperature less than the first temperature.

3. The method of claim 2 wherein cooling the underfill comprises:
before the underfill is dispensed onto the substrate, cooling the underfill to the second temperature.

4. The method of claim 2 further comprising:
before the underfill is dispensed onto the substrate, cooling the substrate such that the underfill cools to the second temperature when dispensed onto the substrate.

5. The method of claim 2 wherein the second temperature is less than room temperature.

6. The method of claim 1 wherein the first temperature ranges from 30° C. to 120° C.

7. The method of claim 1 wherein the vacuum condition is characterized by a sub-atmospheric pressure that does not significantly or detrimentally modify the physical properties of the underfill.

8. The method of claim 1 wherein the vacuum condition is characterized by a sub-atmospheric pressure greater than or equal to 95 Torr.

9. The method of claim 1 where the underfill is a solid underfill that will be brought to a temperature above its melting point to initiate capillary underfill.

10. The method of claim 1 wherein at least one gap is provided in the underfill, and the space is evacuated through the at least one gap.

11. The method of claim 1 wherein no gap is provided in the underfill, and gas in the space bubbles through the underfill while the vacuum condition is being applied.

12. The method of claim 1 wherein the conductive joints are reflowed solder balls.

13. The method of claim 1 wherein the conductive joints are copper pillars.
